(19) United States
(12) Patent Application Publication
(10) Pub. No.: US 2002/0176470 A1
(43) Pub. Date: Nov. 28, 2002

(54) Phase compensated distributed bragg reflector

(76) Inventors: Kevin J. Knopp, Amesbury, MA (US); Peidong Wang, Billerica, MA (US); Daryoosh Vakhshoori, Cambridge, MA (US)

Correspondence Address: Pandiscio & Pandiscio, 470 Totten Pond Road, Waltham, MA, 02451-1914, US

(21) Appl. No.: 10/020,068

(22) Filed: Dec. 14, 2001

Related U.S. Application Data
(60) Provisional application No. 60/276,402, filed on Mar. 16, 2001.

(51) Int. Cl. H01S 5/00; H01S 3/091; H01S 3/092; H01S 3/08

(52) U.S. Cl. 372/70; 372/92; 372/43

(57) ABSTRACT

In one form of the invention, there is provided a laser comprising a front mirror and a rear mirror being disposed so as to establish a reflective cavity therebetween; a gain region disposed between the front mirror and the rear mirror, the gain region being constructed so that when the gain region is appropriately stimulated by light from a pump laser, the gain region will emit light; and the rear mirror having a phase compensated reflector to act as an output coupler for a lasing mode and to reflect pump light at a proper phase so as to provide a second pumping pass through the gain region; wherein the gain region is positioned relative to the rear mirror so as to position the peaks of the reflected pump light in alignment with said gain region during the second pumping pass therethrough; and wherein the gain region is positioned relative to said front mirror and said rear mirror so as to provide proper lasing. In one preferred form of the invention, the gain region is formed by multiple quantum wells (MQW).

### REFERENCE TO PENDING PRIOR PATENT APPLICATION

This patent application claims benefit of pending prior U.S. Provisional Patent Application Serial No. 60/276,402, filed Mar. 16/01 by Kevin J. Knopp et al. for VERTICAL-CAVITY SURFACE-EMITTING LASER WITH CAVITY COMPENSATED GAIN (Attorney's Docket No. CORE-79 PROV), which patent application is hereby incorporated herein by reference.

### FIELD OF THE INVENTION

This invention relates to photonic devices in general, and more particularly to lasers.

### BACKGROUND OF THE INVENTION

Lasers are well known in the art. A laser typically comprises a front mirror and a rear mirror which are disposed so as to establish a reflective cavity therebetween. An active, or gain, region is disposed between the front mirror and rear mirror. The gain region is constructed so that when the gain region is appropriately stimulated, the gain region will emit light. The rear mirror is typically substantially fully reflective at the lasing wavelength, and the front mirror is typically partially reflective at the lasing wavelength so as to allow a beam of laser light to be emitted therefrom.

As is well known in the art, the gain region may be stimulated by electrical current (“electrically pumped”) or it may be stimulated by light (“optically pumped”).

The present invention is directed to optically pumped lasers and, more particularly, to an improved optically pumped laser having an increased observed, or “wall-plug”, efficiency.

### SUMMARY OF THE INVENTION

The present invention comprises an improved optically pumped laser having increased efficiency.

In one form of the invention, there is provided a laser comprising:

a front mirror and a rear mirror being disposed so as to establish a reflective cavity therebetween;

a gain region disposed between the front mirror and the rear mirror, the gain region being constructed so that when the gain region is appropriately stimulated by light from a pump laser, the gain region will emit light; and

the rear mirror having a phase compensated reflector to act as an output coupler for a lasing mode and to reflect pump light at a proper phase so as to provide phase shifted reflected pump light for a second pumping pass through the gain region;

wherein the gain region is positioned relative to the rear mirror so as to position the peaks of the reflected pump light in alignment with the gain region during the second pumping pass therethrough; and

wherein the gain region is positioned relative to the front mirror and the rear mirror so as to provide proper lasing.

### BRIEF DESCRIPTION OF THE DRAWINGS

These and other features of the present invention will be more fully disclosed by the following detailed description of the preferred embodiments of the invention, which is to be considered together with the accompanying drawings wherein like numbers refer to like parts and further wherein:

FIG. 1 is a schematic diagram showing how the pump light is reflected by the rear mirror so as to make two optical pumping passes through the gain region;

FIG. 2 is a graphical diagram of a plot in terms of magnitude and phase of reflectance for a conventional distributed Bragg reflector mirror over a wavelength spectrum including a pump wavelength and a lasing wavelength;

FIG. 3 is a graphical diagram of a plot for in terms of magnitude and phase of reflectance for a conventional dielectric distributed Bragg reflector over a wavelength spectrum including a pump wavelength and a lasing wavelength; and

FIG. 4 is a schematic side sectional view of a tunable VCSEL formed in accordance with the present invention.

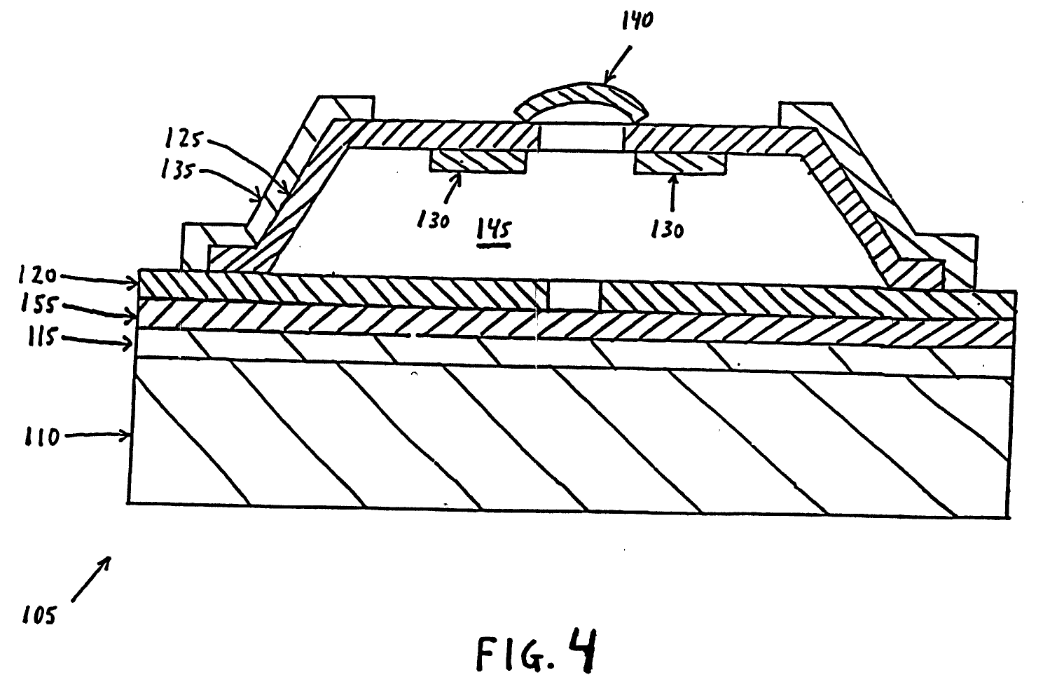

### DETAILED DESCRIPTION OF THE PREFERRED EMBODIMENTS

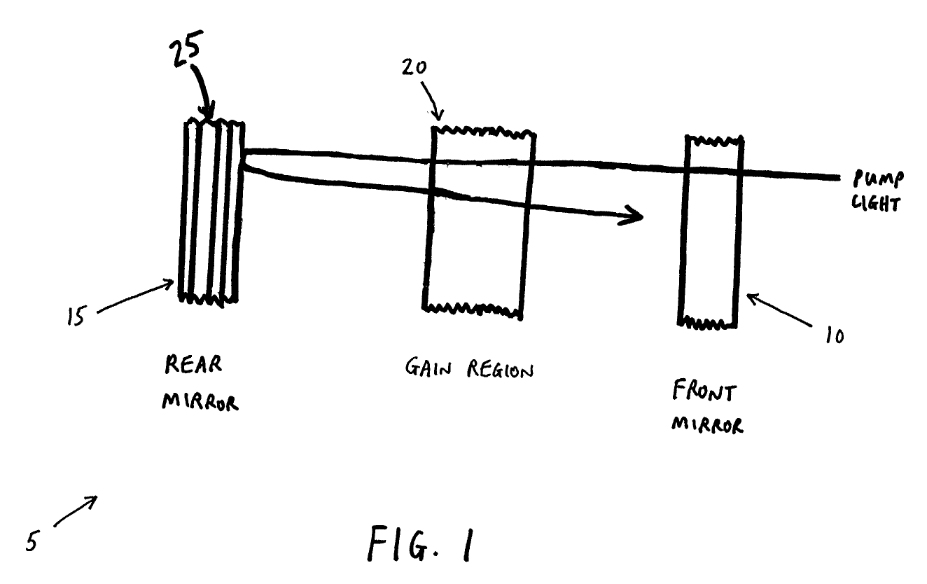

Looking first at FIG. 1, there is shown a schematic diagram of a novel laser 5 formed in accordance with the present invention.

Laser 5 comprises a front mirror 10 and a rear mirror 15 which are disposed so as to establish a reflective cavity therebetween.

A gain region 20 is disposed between front mirror 10 and rear mirror 15. The gain region is constructed so that when the gain region is appropriately stimulated by light from a pump laser, gain region 20 will emit light.

One of front mirror 10 and rear mirror 15 is substantially fully reflective at the lasing wavelength, and the other of front mirror 10 and rear mirror 15 is partially reflective at the lasing wavelength so as to allow a beam of laser light to be emitted therefrom.

Rear mirror 15 is configured to be reflective at the pump wavelength and rear mirror 15 is spaced appropriately so as to cause the pump light to be reflected from rear mirror 15 to make a second pumping pass through gain region 20, whereby to yield increased efficiency.

In one preferred form of the invention, gain region 20 is formed by multiple quantum wells (MQW).

The composition and spacing of front mirror 10, rear mirror 15 and gain region 20 are coordinated with the lasing wavelength, and the composition and spacing of front mirror 10, rear mirror 15 and gain region 20 are coordinated with the pump wavelength so as to provide a laser with increased efficiency. By way of example, where the pump wavelength is λₚ and the lasing wavelength is λ_{L}. Front mirror 10 and rear mirror 15 might comprise distributed Bragg reflectors formed out of alternating layers of quarter-wavelength thick deposited dielectric films (e.g., Si and SiO₂), or semiconductor distributed Bragg reflectors formed out of a semiconductor material such as Si, GaAs, InP, AlGaAs, InGaAsP, InAlGaAs, InAlAs, AlGaAsSb and/or AlAsSb, with at least one layer of rear mirror 15 having a greater thickness so as to form a phase compensating cavity 25 therein; gain region 20 might comprise a multiple quantum well (MQW) structure, e.g., a structure including InGaAsP, InGaAs, GaAs, AlGaAs, InAlGaAs, InAlAs, AlGaAsSb and/or AlAsSb; front mirror 10 might be spaced from rear mirror 15 by 100 nm-10 cm, gain region 20 might have a thickness of 10 nm-100 μm and be spaced from rear mirror 15 by 100 nm-10 cm and be spaced from front mirror 10 by 100 nm-10 cm.

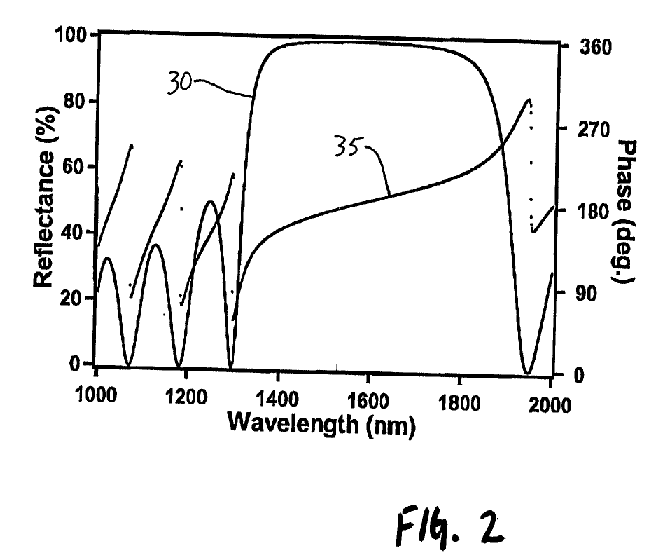

Looking next at FIG. 2, there is shown a graphical diagram of reflected light from a rear mirror comprising a conventional distributed Bragg reflector. A plot 30 shows a percentage of light reflectance, and a plot 35 shows the phase of the light in degrees, over a wavelength spectrum for the conventional mirror. This wavelength spectrum includes a typical pump wavelength of 1310 nm and a typical lasing wavelength of 1550 nm. A high reflectance is achieved at the lasing wavelength, while a lower reflectance is achieved at the pump wavelength, with this conventional mirror. The phase of the reflected light has a low dispersion over the range from the pumping wavelength to the lasing wavelength. Accordingly, the phase is about 180° for both the pump wavelength of light and the lasing wavelength of light.

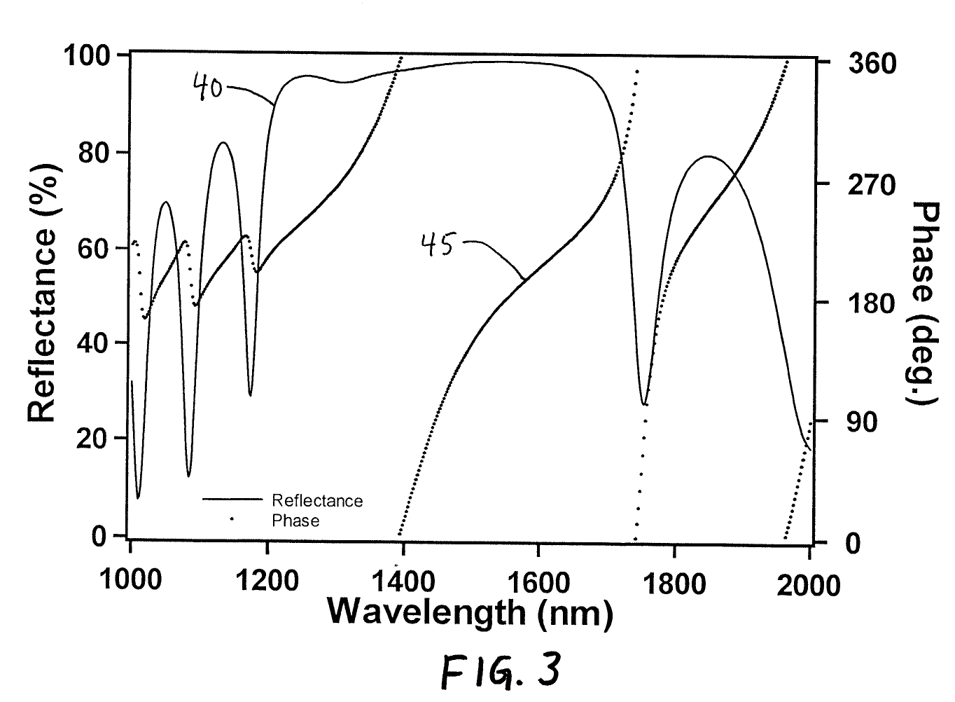

Now referring to FIG. 3, there is shown a graphical diagram of reflected light from a laser including rear mirror 15 comprising a phase compensated distributed Bragg reflector. A plot 40 shows a percentage of light reflectance, and a plot 45 shows the phase of the light in degrees, over a wavelength spectrum for this phase compensated mirror. This wavelength spectrum includes the typical pump wavelength of 1310 nm and the typical lasing wavelength of 1550 nm. A high reflectance is maintained at both the pump wavelength and the lasing wavelength for the phase compensated mirror. However, the phase of the reflected light is modified so as to achieve a specific profile over the range from the pumping wavelength to the lasing wavelength. Accordingly, the phase is about 270° at the pump wavelength and about 180° at the lasing wavelength. As such, rear mirror 15, which comprises a phase compensated distributed Bragg reflector, acts as an output coupler for the lasing mode while also causing pump light to be reflected at the proper phase so as to provide a second pumping pass through the gain region 20 (FIG. 1).

The present invention may be applied to fixed wavelength lasers (i.e., novel laser 5 may comprise an optically pumped fixed wavelength laser) and to tunable lasers (i.e., novel laser 5 may comprise an optically pumped fixed wavelength laser).

In one preferred form of the invention, the optically pumped laser 5 is a tunable vertical-cavity surface-emitting laser (VCSEL) of the sort disclosed in pending prior U.S. patent application Ser. No. 09/105,399, filed Jun. 26, 1998 by Parviz Tayebati et al. for MICROELECTROMECHANICALLY TUNABLE, CONFOCAL, VERTICAL CAVITY SURFACE EMITTING LASER AND FABRY-PEROT FILTER (Attorney's Docket No. CORE-33), and in pending prior U.S. patent application Ser. No. 09/543,318, filed Apr. 05, 2000 by Peidong Wang et al. for SINGLE MODE OPERATION OF MICROELECTROMECHANICALLY TUNABLE, HALF-SYMMETRIC, VERTICAL CAVITY SURFACE EMITTING LASERS (Attorney's Docket No. CORE-53), and in pending prior U.S. patent application Ser. No. 09/750,434, filed Dec. 28, 2000 by Peidong Wang et al. for TUNABLE FABRY-PEROT FILTER AND TUNABLE VERTICAL CAVITY SURFACE EMITTING LASER (Attorney's Docket No. CORE-67). The three aforementioned patent applications are hereby incorporated herein by reference.

More particularly, and looking now at FIG. 3, there is shown a tunable VCSEL 105. VCSEL 105 generally comprises a substrate 110, a bottom mirror 115 mounted to the top of substrate 110, a bottom electrode 120 mounted to the top of bottom mirror 115, a thin membrane support 125 atop bottom electrode 120, a top electrode 130 fixed to the underside of thin membrane support 125, a reinforcer 135 fixed to the outside perimeter of thin membrane support 125, and a confocal top mirror 140 set atop thin membrane support 125, with an air cavity 145 being formed between bottom mirror 115 and top mirror 140.

As a result of this construction, a Fabry-Perot cavity is effectively created between top mirror 140 and bottom mirror 115. Furthermore, by applying an appropriate voltage across top electrode 130 and bottom electrode 120, the position of top mirror 140 can be changed relative to bottom mirror 115, whereby to change the length of the lasing Fabry-Perot cavity.

A gain region (or “active region”) 155 is positioned between bottom mirror 115 and bottom electrode 120. As a result, when gain region 155 is appropriately stimulated, e.g., by optical pumping, lasing can be established between top mirror 140 and bottom mirror 115. Furthermore, by applying an appropriate voltage across top electrode 130 and bottom electrode 120, the position of top mirror 140 can be changed relative to bottom mirror 115, whereby to change the length of the laser's resonant cavity, and hence tune VCSEL 105.

In accordance with the present invention, top mirror 140 is substantially fully reflective at the lasing wavelength, and bottom mirror 115 is partially reflective at the lasing wavelength so as to allow a beam of laser light to be emitted therefrom.

The gain region 155 is preferably formed by MQW.

Bottom mirror 115 is reflective at the pump wavelength so as to cause the pump light to be reflected by the bottom mirror 115 so that the pump light will make a second pumping pass through gain region 155, whereby to yield increased observed, or “wall-plug”, efficiencies.

It is to be understood that the present invention is by no means limited to the particular constructions and method steps disclosed above and/or shown in the drawings, but also comprises any modifications or equivalents within the scope of the claims.

What is claimed is:

1. A laser comprising:
a front mirror and a rear mirror being disposed so as to establish a reflective cavity therebetween;
a gain region disposed between said front mirror and said rear mirror, said gain region being constructed so that when said gain region is appropriately stimulated by light from a pump laser, said gain region will emit light; and
said rear mirror having a phase compensated reflector to act as an output coupler for a lasing mode and to reflect pump light at a proper phase so as to provide phase shifted reflected pump light for a second pumping pass through said gain region;
wherein said gain region is positioned relative to said rear mirror with said peaks of said reflected pump light in alignment with said gain region during said second pumping pass therethrough; and
wherein said gain region is positioned relative to said front mirror and said rear mirror so as to provide proper lasing.

2. A laser according to claim 1 wherein said gain region is formed by multiple quantum wells (MQW).

3. A laser according to claim 1 wherein said rear mirror is configured to reflect light at said wavelength of said pump laser with a phase of 270°.

4. A laser according to claim 1 wherein said rear mirror is configured to reflect light at a wavelength for lasing with phase of 180°.

5. A laser according to claim 1 wherein said rear mirror comprises a distributed Bragg reflector.

6. A laser according to claim 5 wherein said distributed Bragg reflector comprises a plurality of layers, and one of said plurality of layers has a greater thickness so as to form said phase compensated reflector.

7. A laser according to claim 5 wherein said one of said plurality of layers is a third layer.

8. A laser according to claim 1 wherein said front mirror comprises a semiconductor distributed Bragg reflector.

9. A laser according to claim 8 wherein said semiconductor distributed Bragg reflector comprises one of a group consisting of Si, GaAs, InP, AlGaAs, InGaAsP, InAlGaAs, InAlAs, AlGaAsSb and AlAsSb.

10. A laser according to claim 1 wherein said rear mirror comprises a semiconductor distributed Bragg reflector.

11. A laser according to claim 10 wherein said semiconductor distributed Bragg reflector comprises one of a group consisting of Si, GaAs, InP, AlGaAs, InGaAsP, InAlGaAs, InAlAs, AlGaAsSb and AlAsSb.

12. A laser according to claim 10 wherein said semiconductor distributed Bragg reflector comprises a plurality of layers, and one of said plurality of layers has a greater thickness so as to form said phase compensated reflector.

13. A laser according to claim 12 wherein said one of said plurality of layers is a third layer.
